(19) United States
(12) Patent Application Publication
(10) Pub. No.: US 2013/0056883 A1
(43) Pub. Date: Mar. 7, 2013

(54) SEMICONDUCTOR DEVICE AND METHOD OF MANUFACTURING THE SAME

(71) Applicant: Osamu FURUKAWA, Hyogo-ken (JP)

(72) Inventor: Osamu FURUKAWA, Hyogo-ken (JP)

(73) Assignee: Kabushiki Kaisha Toshiba, Tokyo (JP)

(21) Appl. No.: 13/425,266

(22) Filed: Mar. 20, 2012

(30) Foreign Application Priority Data
Sep. 1, 2011 (JP) 2011-191010

(51) Int. Cl. H01L 23/48; H01L 21/50

(52) U.S. Cl. 257/782; 438/127; 257/E23.01; 257/E21.499

(57) ABSTRACT

According to one embodiment, a semiconductor device includes a base board, a mounting substrate, a semiconductor element, a holder, a holder terminal, a case, a first sealing layer, and a second sealing layer. The mounting substrate is provided on the base board. The semiconductor element is provided on the mounting substrate. The holder is provided above the mounting substrate. The holder terminal is held by the holder and electrically connected to the semiconductor element. The case surrounds the mounting substrate along a side face of the mounting substrate and surrounds the holder along a side face of the holder. The first sealing layer covers the mounting substrate and the semiconductor element inside a space surrounded by the case. The second sealing layer is provided on the first sealing layer inside the space surrounded by the case and has a higher hardness than the first sealing layer.

### CROSS-REFERENCE TO RELATED APPLICATIONS

This application is based upon and claims the benefit of priority from the prior Japanese Patent Application No. 2011-191010, filed on Sep. 1, 2011; the entire contents of which are incorporated herein by reference.

### FIELD

Embodiments described herein relate generally to a semiconductor device and a method for manufacturing the same.

### BACKGROUND

In power semiconductor devices, a semiconductor chip is provided on a base board, and a terminal held by a holder provided above the semiconductor chip and the semiconductor chip are electrically connected to each other. In addition, a sealing member is filled in between the base board and the terminal holder.

In such semiconductor devices, it is preferable to prevent the occurrence of a crack, peel-off, or the like in the sealing member and the like and acquire high reliability.

### BRIEF DESCRIPTION OF THE DRAWINGS

FIG. 1 is a schematic cross-sectional view illustrating the configuration of a semiconductor device according to a first embodiment;

FIG. 2 is a schematic cross-sectional view illustrating the configuration of a semiconductor device according to a second embodiment;

FIGS. 3A and 3B are flowchart diagrams illustrating a method for manufacturing a semiconductor device according to the third embodiment;

FIGS. 4A to 4C are sequential schematic cross-sectional views illustrating the method for manufacturing a semiconductor device according to the third embodiment; and

FIGS. 5A to 5C are sequential schematic cross-sectional views illustrating another method for manufacturing a semiconductor device according to the third embodiment.

### DETAILED DESCRIPTION

According to one embodiment, a semiconductor device includes a base board, a mounting substrate, a semiconductor element, a holder, a holder terminal, a case, a first sealing layer, and a second sealing layer. The mounting substrate is provided on the base board. The semiconductor element is provided on the mounting substrate. The holder is provided above the mounting substrate. The holder terminal is held by the holder and electrically connected to the semiconductor element. The case surrounds the mounting substrate along a side face of the mounting substrate and surrounds the holder along a side face of the holder. The first sealing layer covers the mounting substrate and the semiconductor element inside a space surrounded by the case. The second sealing layer is provided on the first sealing layer inside the space surrounded by the case and has a hardness higher than a hardness of the first sealing layer.

According to another embodiment, a semiconductor device includes a base board, a mounting substrate, a semiconductor element, a holder, a holder terminal, a case, a first sealing layer, and a second sealing layer. The mounting substrate is provided on the base board. The semiconductor element is provided on the mounting substrate. The holder is provided above the mounting substrate. The holder terminal is held by the holder and electrically connected to the semiconductor element. The case surrounds the mounting substrate along a side face of the mounting substrate and surrounds the holder along a side face of the holder. The first sealing layer covers the mounting substrate and the semiconductor element inside a space surrounded by the case. The second sealing layer is provided on the first sealing layer inside the space surrounded by the case and is more difficult to be deformed than the first sealing layer.

According to another embodiment, a method is disclosed for manufacturing a semiconductor device. The device includes a base board; a mounting substrate provided on the base board; a semiconductor element provided on the mounting substrate; a holder provided above the mounting substrate; a holder terminal held by the holder and electrically connected to the semiconductor element; a case surrounding the mounting substrate along a side face of the mounting substrate and surrounding the holder along a side face of the holder; and a sealing portion covering the mounting substrate and the semiconductor element inside a space surrounded by the case. The method can include forming a first sealing layer covering the mounting substrate and the semiconductor element inside the space surrounded by the case and forming a part of the sealing portion. The method can include forming a second sealing layer disposed on the first sealing layer inside the space surrounded by the case, having a hardness higher than a hardness of the first sealing layer, and serving as a part of the sealing portion.

Various embodiments will be described hereinafter with reference to the accompanying drawings.

Here, the drawings are schematic or conceptual ones, and the relation between the thickness and the width of each portion, the ratio between the sizes of portions, and the like are not real. In addition, even in a case where the same portion is illustrated, the dimension or the ratio thereof may be differently illustrated in the drawings.

In addition, in the description presented in the application and the drawings, the same reference numeral is assigned to the same element as that described with reference to a previous drawing, and detailed description thereof will not be presented as is appropriate.

### First Embodiment

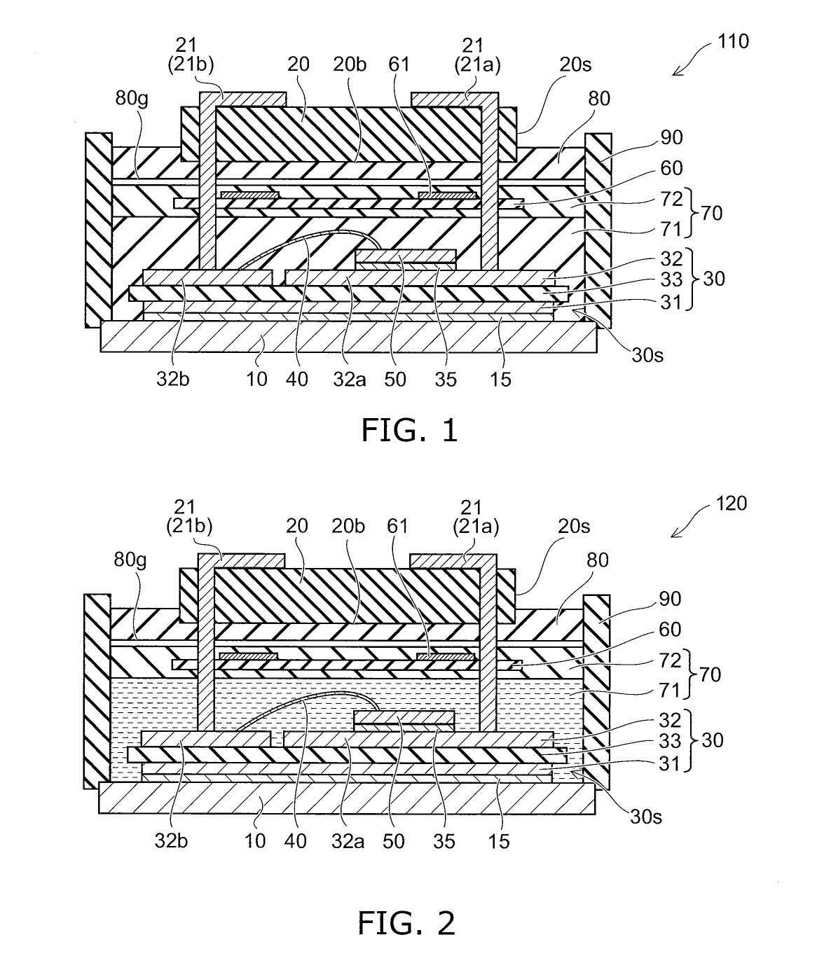

FIG. 1 is a schematic cross-sectional view illustrating the configuration of a semiconductor device according to a first embodiment.

As illustrated in FIG. 1, the semiconductor device 110 according to the embodiment includes a base board 10, a mounting substrate 30, a semiconductor element 50, a holder 20, holder terminals 21, a case 90, a first sealing layer 71, and a second sealing layer 72.

The semiconductor element 50 is one of various types of power semiconductor elements such as a thyristor, a diode, a transistor, and the like. In other words, the semiconductor device 110, for example, is a power module of a resin sealing type.

The mounting substrate 30 is provided on the base board 10. The semiconductor element 50 is provided on the mounting substrate 30. The holder 20 is provided above the mounting substrate 30. The holder terminals 21 are held by the holder 20. The holder terminals 21 are electrically connected to the semiconductor element 50. The case 90 surrounds the mounting substrate 30 along the side face 30s of the mounting substrate 30, and surrounds the holder 20 along the side face 20s of the holder 20. The first sealing layer 71 covers the mounting substrate 30 and the semiconductor element 50 on the inner side (inside a space surrounded by the case 90) of the case 90. The second sealing layer 72 is provided on the first sealing layer 71 on the inner side (inside the space surrounded by the case 90) of the case 90. The hardness of the second sealing layer 72 is higher than the hardness of the first sealing layer 71. For example, the second sealing layer 72 is more difficult to be deformed than the first sealing layer 71. For example, as will be described later, the penetration of the second sealing layer 72 is lower than the penetration of the first sealing layer 71.

As the base board 10, for example, a metal board, a composite material board formed from a material such as AlSiC, or the like is used. For example, the base board 10 has a function of dissipating heat that is generated by the semiconductor element 50.

For example, the mounting substrate 30 may include a ceramic board 33, a lower circuit layer 31, and an upper circuit layer 32. The lower circuit layer 31 is provided on a face of the ceramic board 33 that is located on a side facing the base board 10. The upper circuit layer 32 is provided on a face of the ceramic board 33 that is located on a side facing the holder 20. For example, the upper circuit layer 32 includes a first upper circuit layer 32a and a second upper circuit layer 32b.

In this example, a bonding layer 15 is provided between the base board 10 and the mounting substrate 30 (more particularly, between the base board 10 and the lower circuit layer 31). As the material of the bonding layer 15, for example, solder is used. Accordingly, the base board 10 and the mounting substrate 30 are thermally connected to each other.

For example, the semiconductor element 50 is provided on the first upper circuit layer 32a. In this example, a semiconductor element bonding layer 35 is provided between the semiconductor element 50 and the first upper circuit layer 32a. As the material of the semiconductor element bonding layer 35, for example, solder is used. In the lower face (a face facing the mounting substrate 30) of the semiconductor element 50, an electrode, which is not illustrated in the figure, is provided. The semiconductor element bonding layer 35 is connected to this electrode. Accordingly, the semiconductor element 50 (one electrode thereof) and the first upper circuit layer 32a are electrically connected to each other. In addition, the semiconductor element 50 and the first upper circuit layer 32a can be thermally connected to each other.

In the upper face (a face located on a side facing the holder 20) of the semiconductor element 50, an electrode not illustrated in the figure is provided. One end of a wire 40 is connected to this electrode. For example, the other end of the wire 40 is connected to the second upper circuit layer 32b. Accordingly, the semiconductor element 50 (the other electrode thereof) and the second upper circuit layer 32b are electrically connected to each other.

In this example, the holder terminal 21 includes a first holder terminal 21a and a second holder terminal 21b. The first holder terminal 21a and the second holder terminal 21b extend from the mounting substrate 30 toward the upper side (a side opposite to the base board 10). The first holder terminal 21a is electrically connected to the first upper circuit layer 32a. The second holder terminal 21b is electrically connected to the second upper circuit layer 32b.

The case 90 is provided on the peripheral edge portion of the base board 10. The case 90 faces the side face 30s of the mounting substrate 30 and the side face of the semiconductor element 50. In addition, the case 90 corresponds to at least a part of the side face 20s of the holder 20. For example, the case 90 surrounds a part of the holder 20 in the thickness direction along the side face 20s of the holder 20. Alternatively, the case 90 surrounds the whole holder 20 in the thickness direction along the side face 20s of the holder 20.

The first sealing layer 71 and the second sealing layer 72 are included in the sealing portion 70. As the material of the first sealing layer 71 and the second sealing layer 72, a material that has a high insulating property and is chemically stable is used. For example, the first sealing layer 71 and the second sealing layer 72 contain silicone gel. In addition, the silicone gel may contain solid particles such as fillers. In the embodiment, the material used for the first sealing layer 71 and the second sealing layer 72 is arbitrary. As will be described later, for example, silicone oil or the like may be used as the material of the first sealing layer 71.

In addition, in this example, the semiconductor device 110 further includes a holder resin layer 80. The holder resin layer 80 is brought into contact with the case 90, at least a part of the side face 20s of the holder 20, and the lower face 20b of the holder 20. In other words, the holder resin layer 80 is brought into contact with at least a part of the side face 20s of the holder 20 and the lower face 20b of the holder 20 inside a space surrounded by the case 90. The hardness of the holder resin layer 80 is higher than the hardness of the second sealing layer 72. For example, the holder resin layer 80 is more difficult to be deformed than the second sealing layer 72. In addition, a gap 80g is present between the second sealing layer 72 and the holder resin layer 80.

As the material of the holder resin layer 80, a material that has high mechanical strength and a high moisture barrier property is used. For example, the holder resin layer 80 contains an epoxy-based resin. However, in the embodiment, a material used for the holder resin layer 80 is arbitrary.

The semiconductor device 110 having such a configuration, for example, is manufactured by arranging the mounting substrate 30, the semiconductor element 50, the case 90, the holder 20, and the holder terminals 21 on the base board 10 and then filling up a material used for forming the sealing portion 70 (the first sealing layer 71 and the second sealing layer 72).

The semiconductor device 110 of the specific example further includes a control circuit board 60. The control circuit board 60 is provided between the mounting substrate 30 and the holder 20. The control circuit board 60 includes a control element 61. For example, the control element 61 is provided on at least one of a holder 20 side face and a mounting substrate 30 side face of the control circuit board 60. The control circuit board 60 is surrounded by the second sealing layer 72.

The control element 61, for example, includes at least one of a resistor, a thermistor, a semiconductor integrated circuit (IC), and the like. In a case where the control element 61 includes an IC, the electrode electrically connected to the control element 61 is electrically connected to the electrode provided on the upper face of the holder 20. These electrodes may be integrally provided.

As described above, the first sealing layer 71 covers the mounting substrate 30 and the semiconductor element 50 inside the case 90. The first sealing layer 71 further covers the wire 40. A gap may be generated between the first sealing layer 71 and the second sealing layer 72 disposed thereon. By covering the wire 40 with the first sealing layer 71, an electrical connection between the semiconductor element 50 and the second upper circuit layer 32b is reliably made.

As described above, the hardness of the second sealing layer 72 is higher than the hardness of the first sealing layer 71. For example, the penetration of the second sealing layer 72 is lower than the penetration of the first sealing layer 71. The penetration represents the softness of a gelatinous material or the like and is a value that is acquired by measuring the depth to which a regulated cone penetrates the material in a regulated time.

For example, the penetration of the first sealing layer 71 is 100 or more and 500 or less. For example, as the material of the first sealing layer 71, silicone gel having penetration of 400 can be used.

In addition, for example, the penetration of the second sealing layer 72 is 10 or more and 100 or less. For example, as the material of the second sealing layer 72, silicone gel having penetration of 40 can be used.

As above, in the embodiment, the hardness of the second sealing layer 72 is high. On the other hand, the hardness of the first sealing layer 71 is low. Alternatively, as will be described later, liquid (oil) is used as the material of the first sealing layer 71.

Accordingly, the occurrence of a crack or peel-off in the sealing member is suppressed, whereby a semiconductor device having high reliability can be acquired.

The inventor has found that a crack or peel-off occurs in a case where one type of material is used as the material of the sealing portion 70.

In other words, in a case where a sealing resin (for example, a silicone resin) is used as the material of the sealing portion 70, residual stress occurs when the sealing resin is thermally cured and contracted. Thus, a crack may occur in the sealing resin due to the residual stress. For example, the sealing rein is vertically thermally expanded and contracted due to the module structure. Then, a crack occurs due to the residual stress remaining in the resin after contraction. This crack vertically extends from the surface (upper face) of the sealing resin toward the mounting substrate 30.

In a case where the crack reaches the mounting substrate 30 or a location near the mounting substrate 30, a required insulating property cannot be acquired. By covering the peripheral portion of the mounting substrate 30 with the sealing resin, the required insulating property can be secured. In addition, it has been determined that such a crack easily occurs particularly in a case where the control circuit board 60 is provided above the mounting substrate 30.

According to an experiment made by the inventor, in a case where a low-penetration (high hardness and high strength) material is used as the sealing resin, while the occurrence of a crack in the sealing resin is enhanced, it has been understood that peel-off can easily occur in the boundary face of the sealing resin and the mounting substrate 30. On the other hand, in a case where a high-penetration material is used as the sealing resin, while peel-off occurring in the boundary face of the sealing resin and the mounting substrate 30 is enhanced, it has been understood that a crack may easily occur in the sealing resin due to the residual stress occurring at a time when the sealing resin is thermally cured and contracted.

The inventor has newly discovered such problems. The embodiment has a configuration for solving such newly discovered problems. In the embodiment, the hardness of the second sealing layer 72 is configured to be higher than the hardness of the first sealing layer 71. In other words, the second sealing layer 72 is configured to be more difficult to be deformed than the first sealing layer 71. In other words, the first sealing layer 71 is configured to be easier to be deformed than the second sealing layer 72. By using a material that can be easily deformed as the material of the first sealing layer 71 that covers the mounting substrate 30, peel-off occurring in the boundary face of the sealing portion 70 and the mounting substrate 30 is suppressed. In addition, by using a high-hardness material as the material of the second sealing layer 72 that is provided on the first sealing layer 71, the occurrence of a crack in the sealing portion 70 is suppressed. In addition, even in a case where a crack occurs in the second sealing layer 72, the crack is stopped at the boundary face of the second sealing layer 72 and the first sealing layer 71, whereby the crack is suppressed from reaching the peripheral portion of the mounting substrate 30. As above, according to the embodiment, the occurrence of a crack in the sealing member is suppressed, and the peel-off of the sealing member is suppressed. Accordingly, a semiconductor device having high reliability can be provided.

In the embodiment, for example, two types of silicone resins including a material that forms a high-penetration first sealing layer 71 and a material that forms a low-penetration second sealing layer 72 are filled in the space located inside the case 90. For example, the space is filled with the material that forms the first sealing layer 71 so as to cover the mounting substrate 30, the semiconductor element 50, and the wire 40, and the material is thermally cured, thereby forming the first sealing layer 71. Thereafter, the space located on the first sealing layer 71 is filled with a material that forms the second sealing layer 72 so as to cover the control circuit board 60, and the material is thermally cured, thereby forming the second sealing layer 72. As above, the peripheral portion of the mounting substrate 30 is filled with a high-penetration resin in which it is difficult for boundary face peel-off to occur. Then, the upper side of the peripheral portion is filled with a low-penetration (high hardness and high strength) resin in which it is difficult for a crack caused by the residual stress at the time of thermal contraction to occur. By employing such a configuration, the occurrence of a crack in the sealing member and the occurrence of peel-off of the sealing member are suppressed.

In a case where the control circuit board 60 is provided, it is preferable that the control circuit board 60 is not covered with the first sealing layer 71 but covered with the second sealing layer 72. A crack may easily occur particularly in a case where the control circuit board 60 is provided. It is understood that the reason for this is that, in the case where the control circuit board 60 is provided, the control circuit board 60 serves as an obstacle at the time of thermal curing and contraction of the sealing portion 70, and the sealing portion 70 is pulled by the control circuit board 60. At this time, the control circuit board 60 is covered with the second sealing layer 72, and the boundary face of the first sealing layer 71 and the second sealing layer 72 is disposed between the mounting substrate 30 and the control circuit board 60. Thus, although a crack occurring on the surface (upper face) of the second sealing layer 72 reaches the boundary face of the first sealing layer 71 and the second sealing layer 72, the crack does not advance to the inside of the first sealing layer 71. As above, in a case where the control circuit board 60 is provided, by disposing the boundary face of the first sealing layer 71 and the second sealing layer 72 between the mounting substrate 30 and the control circuit board 60, the occurrence of a crack in the sealing member and peel-off of the sealing member can be suppressed more efficiently.

In addition, in the embodiment, the holder resin layer 80 is provided, and the case 90 and the holder 20 are fixed by the holder resin layer 80, whereby the strength is improved further. At this time, by providing the gap 80g between the second sealing layer 72 and the holder resin layer 80, the heat resistance of the semiconductor device 110 is improved further.

In other words, the hardness of the holder resin layer 80 is higher than the hardness of the sealing portion 70 (the first sealing layer 71 and the second sealing layer 72). In other words, the holder resin layer 80 is difficult to be deformed than the sealing portion 70. The thermal expansion coefficient of the holder resin layer 80 is larger than the thermal expansion coefficient of the sealing portion 70 (the first sealing layer 71 and the second sealing layer 72). In a reference example in which the second sealing layer 72 and the holder resin layer 80 contact each other so as not to provide the gap 80g, when the semiconductor device is maintained at high temperature, the sealing portion 70 expands much, and, for example, peel-off occurs between the holder resin layer 80 and the case 90, whereby the semiconductor device may be broken.

In contrast to this, in the semiconductor device 110 according to the embodiment, by providing the gap 80g between the second sealing layer 72 and the holder resin layer 80, even when the semiconductor device 110 is maintained at high temperature, the breakdown of the semiconductor device due to the expansion of the sealing portion 70 is suppressed.

It is not necessary to provide the gap 80g, which is formed between the second sealing layer 72 and the holder resin layer 80, over the whole face between the second sealing layer 72 and the holder resin layer 80. For example, a part of the second sealing layer 72 may contact the holder resin layer 80. In addition, a part of the holder resin layer 80 may contact the second sealing layer 72. In other words, between the second sealing layer 72 and the holder resin layer 80, a space may be provided in which the sealing portion 70 (the first sealing layer 71 and the second sealing layer 72) can be deformed (for example, deformed due to the thermal expansion). One or a plurality of the gaps 80g may be provided.

In addition, in the configuration in which the semiconductor chip is covered with a plurality of resin layers, there is the configuration of a reference example in which the expansion rate, the elastic modulus, or the viscosity of an inner resin layer is lower than that of an outer resin layer. For example, the semiconductor chip is covered with a material that has a low expansion rate, and the periphery of the semiconductor chip is covered with a material that has a high expansion rate. In this configuration, the peel-off of the resin and a crack in the resin that occur due to the heat radiation of the semiconductor chip during its operation are intended to be suppressed. Accordingly, by employing such a configuration, it is difficult to solve the problems expected to be solved in the application.

In other words, in the semiconductor device as the object of the application, while the upper faces and the side faces of the semiconductor element 50 and the mounting substrate 30 are covered with the sealing portion 70, the sealing portion 70 is not disposed on the lower side of the mounting substrate 30. The lower face of the mounting substrate 30 is bonded to the base board 10 through the bonding layer 15 (solder layer). Accordingly, the configuration of the reference example is different from the configuration of the semiconductor device as the object of the application.

A crack in the sealing portion 70 and peel-off from the boundary face of the sealing portion 70 and the mounting substrate 30, which are caused by the residual stress at the time of thermal curing and contraction, can be suppressed in the embodiment.

In addition, there is a configuration in which a semiconductor element, a first resin that coats the semiconductor element, a second resin which has hardness higher than the first resin and coats the first resin, and a molding resin that coats and shapes the periphery of the second resin are included. In such a configuration, the second resin and the molding resin tightly contact each other, and a gap is not formed. In addition, in such a configuration, for example, air bubbles are generated in the first resin due to stress according to a difference in the thermal expansion coefficient. Accordingly, the stress is relaxed.

In contrast this, according to the embodiment, by providing the gap 80g between the second sealing layer 72 and the holder resin layer 80, air bubbles are suppressed from being generated in the sealing portion 70 (for example, in the first resin layer 71). Accordingly, compared to a case where air bubbles are generated in the sealing portion 70, the stress can be relaxed relatively effectively. In addition, the operation of the semiconductor element 50 is more stabilized than the operation of a case where air bubbles are generated in the sealing portion 70.

### Second Embodiment

FIG. 2 is a schematic cross-sectional view illustrating the configuration of a semiconductor device according to a second embodiment.

As shown in FIG. 2, the semiconductor device 120 according to the embodiment includes a base board 10, a mounting substrate 30, a semiconductor element 50, a holder 20, holder terminals 21, a case 90, a first sealing layer 71, and a second sealing layer 72. In addition, the semiconductor device 120 includes a holder resin layer 80, and there is a gap 80g between the second sealing layer 72 and the holder resin layer 80. Furthermore, the semiconductor device 120 additionally includes a control circuit board 60. The control circuit board 60 is surrounded by the second sealing layer 72.

In the semiconductor device 120, the first sealing layer 71 is liquid. For example, the first sealing layer 71 contains silicone oil. On the other hand, silicone gel is used as the material of the second sealing layer 72. Also in such a case, the second sealing layer 72 is more difficult to be deformed than the first sealing layer 71. In other words, the first sealing layer 71 is easier to be deformed than the second sealing layer 72.

For example, the region above the mounting substrate 30, the semiconductor element 50, and the wire 40 is filled with a material that forms the second sealing layer 72 so as to cover the control circuit board 60, and the material is thermally cured, thereby forming the second sealing layer 72. Thereafter, for example, silicone oil that forms the first sealing layer 71 is injected by a dispenser through a hole that is formed in the second sealing layer 72 by the dispenser. The silicon oil covers the mounting substrate 30, the semiconductor element 50, and the wire 40. The hole is sealed as is necessary. The second sealing layer 72, for example, seals the silicon oil included in the first sealing layer 71. By employing such a configuration, in the peripheral portion of the mounting substrate 30, neither peel-off of the boundary face nor a crack occurs. By filling the periphery of the mounting substrate 30, which preferably has a high insulating property, with the silicone oil, a crack in the sealing member and the peel-off of the sealing member are suppressed, whereby a semiconductor device having high reliability can be provided.

In addition, it may be configured such that the first sealing layer 71 is formed so as to cover the mounting substrate 30, the semiconductor element 50, and the wire 40 by injecting silicone oil that forms the first sealing layer 71, thereafter, the region above the first sealing layer 71 is filled with a material that forms the second sealing layer 72 so as to cover the control circuit board 60, and the material is thermally cured.

In the first and second embodiments, although a case has been described in which the first sealing layer 71 and the second sealing layer 72 are provided as the sealing portion 70, the embodiments are not limited thereto. For example, a third sealing layer and the like may be provided between the first sealing layer 71 and the second sealing layer 72. In other words, two or more layers having characteristics different from each other may be used as the sealing portion 70. For example, two or more layers having the degrees of penetration different from one another may be used as the sealing portion 70.

By using two or more types of resins having the hardness different from one another (the degree of deformation is different) as the sealing portion 70, when a crack reaches the boundary face of the plurality of resins, the crack does not penetrate into a resin that is located on the lower side. The crack extends in the horizontal direction along the boundary face of the plurality of resins. Accordingly, the insulating property of the peripheral portion of the mounting substrate 30 is secured.

In a case where two or more types of resins having mutually different degrees of penetration are used, particularly, a resin having low penetration, in which it is difficult for a crack due to residual stress according to thermal contraction to occur, is used for the upper portion (surface-side portion). Accordingly, the occurrence of a crack that extends from the upper portion toward the mounting substrate 30 is suppressed. In addition, a resin having high penetration is used for the lower portion. Accordingly, the occurrence of peel-off is suppressed. Therefore, while the peel-off of the peripheral portion of the mounting substrate 30 is suppressed, the occurrence of a crack in the resin can be suppressed.

By using liquid (for example, silicone oil) as the material of the first sealing layer 71, compared to a case where a gelatinous material is used, the generation of air bubbles and the occurrence of a crack, peel-off, and the like can be suppressed further. In addition, a higher insulating property of the mounting substrate 30 can be secured.

### Third Embodiment

The embodiment relates to a method for manufacturing a semiconductor device. The manufacturing method is a method for manufacturing a semiconductor device that, for example, includes a base board 10, a mounting substrate 30, a semiconductor element 50, a holder 20, holder terminals 21, a case 90, and a sealing portion 70.

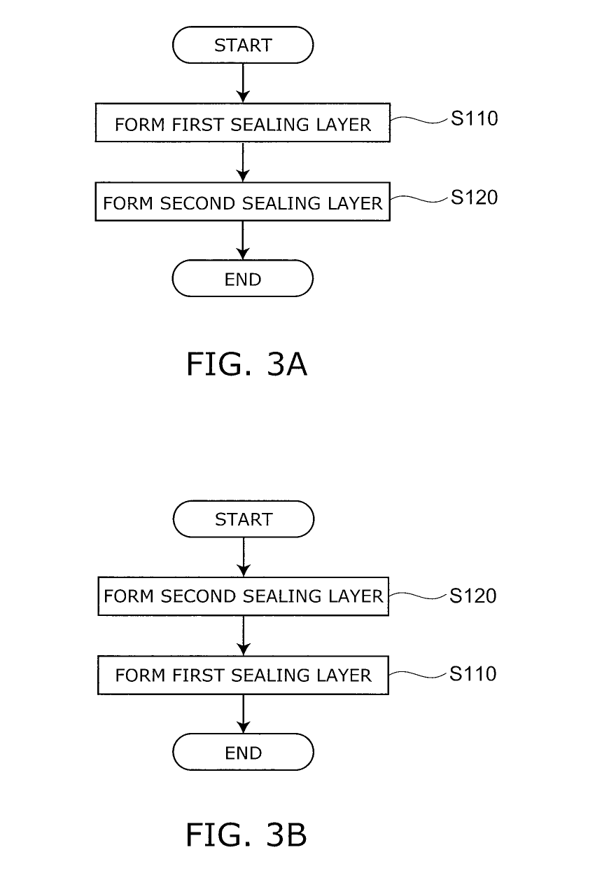

FIGS. 3A and 3B are flowchart diagrams illustrating a method for manufacturing a semiconductor device according to the third embodiment.

As shown in FIGS. 3A and 3B, the manufacturing method includes a process (Step S110) of forming the first sealing layer 71 and a process of forming the second sealing layer 72 (Step S120).

The first sealing layer 71, for example, covers the mounting substrate 30 and the semiconductor element 50 inside a space surrounded by the case 90. The first sealing layer 71 forms a part of the sealing portion 70. The second sealing layer 72, for example, is disposed on the first sealing layer 71 inside the space surrounded by the case 90. The second sealing layer 72 forms another part of the sealing portion 70. For example, the hardness of the second sealing layer 72 is higher than the hardness of the first sealing layer 71. For example, the second sealing layer 72 is more difficult to be deformed than the first sealing layer 71. For example, the penetration of the second sealing layer 72 is lower than that of the first sealing layer.

As illustrated in FIGS. 3A and 3B, the order of Step S110 and Step S120 may be changed.

As described above, in a case where the semiconductor device to be manufactured further includes the control circuit board 60, the forming of the second sealing layer 72 includes forming the second sealing layer 72 such that the second sealing layer 72 surrounds the control circuit board 60.

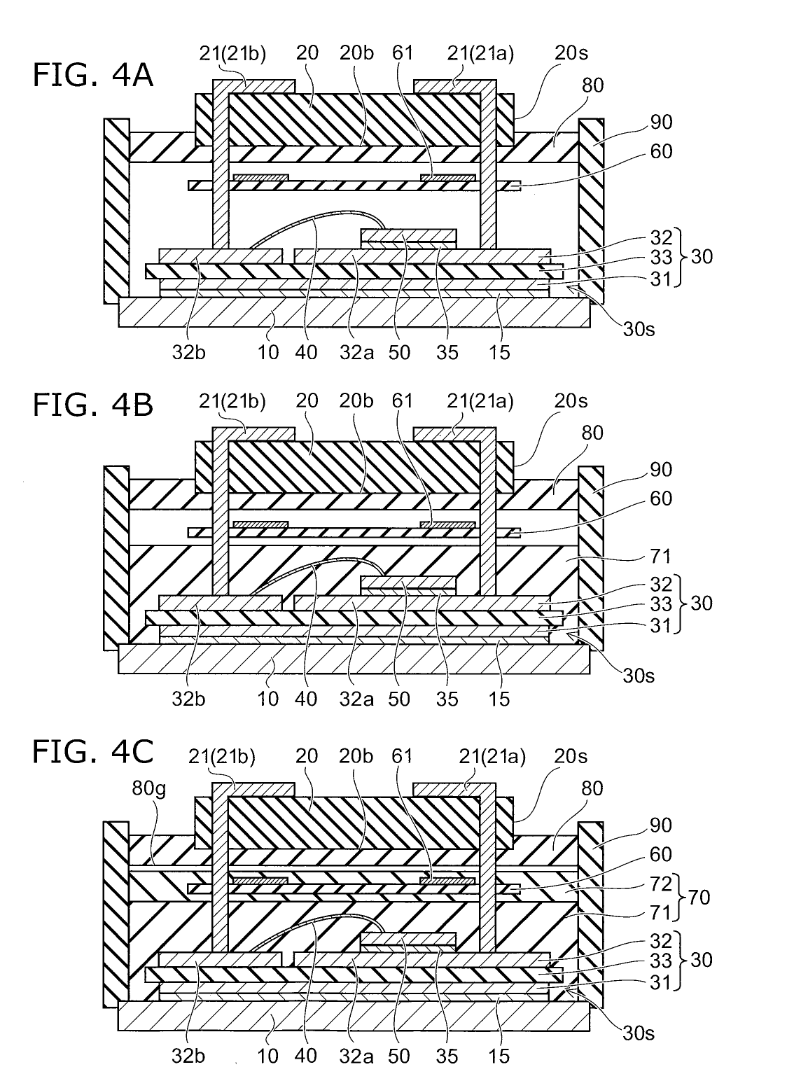

FIGS. 4A to 4C are sequential schematic cross-sectional views illustrating the method of manufacturing a semiconductor device according to the third embodiment.

As shown in FIG. 4A, the semiconductor element 50 is mounted on the mounting substrate 30, and, additionally, for example, bonding of the wire 40 is performed. Then, for example, according to a reflow system, the lower circuit layer 31 of the mounting substrate 30 and the base board 10 are connected to each other by the bonding layer 15, and a connection between the holder terminal 21 (for example, the first holder terminal 21a and the second holder terminal 21b) and the upper circuit layer 32 (for example, the first upper circuit layer 32a and the second upper circuit layer 32b) of the mounting substrate 30 is made. Then, the case 90 is installed. In addition, such a process may be included in the manufacturing method according to the embodiment.

Thereafter, as shown in FIG. 4B, the first sealing layer 71 is formed so as to cover the mounting substrate 30 and the semiconductor element 50 inside the space surrounded by the case 90. In particular, for example, the filling of a material forming the first sealing layer 71 is performed so as to cover the mounting substrate 30, the semiconductor element 50, and the wire 40, and the material is thermally cured. Accordingly, the first sealing layer 71 is formed. The filling, for example, is performed through at least one of the hole provided in the holder resin layer 80 and a gap between the holder resin layer 80 and the case 90.

Thereafter, as shown in FIG. 4C, the second sealing layer 72 is formed on the first sealing layer inside the space surrounded by the case 90. In particular, the region above the first sealing layer 71 is filled with a material that forms the second sealing layer 72, and the material is thermally cured. Accordingly, the second sealing layer 72 is formed. In addition, in a case where the control circuit board 60 is provided, the filling of a material that forms the second sealing layer 72 is performed so as to cover the control circuit board 60, and the material is thermally cured. For example, the first sealing layer 71 and the second sealing layer 72 are formed from silicone gel.

Accordingly, for example, a semiconductor light emitting device 110 is formed.

In addition, it is preferable that the forming of the second sealing layer 80 includes forming of the second sealing layer 72 such that the gap 80g is formed between the second sealing layer 72 and the holder resin layer 80. Accordingly, the heat resistance of the manufactured semiconductor device is further improved.

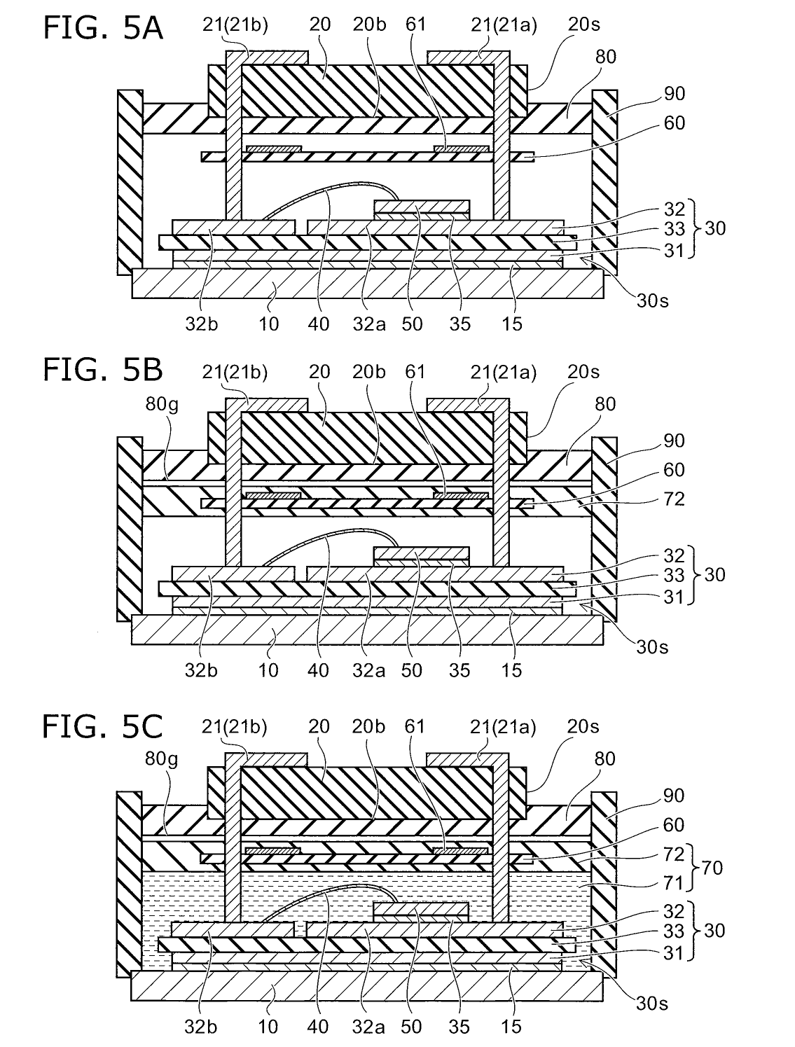

FIGS. 5A to 5C are sequential schematic cross-sectional views illustrating another method for manufacturing a semiconductor device according to the third embodiment.

As shown in FIG. 5A, mounting of the semiconductor element 50 on the mounting substrate 30, bonding of the wire 40, bonding of the mounting substrate 30 and the base board 10, connecting of the holder terminals 21 and the mounting substrate 30, and installation of the case 90 are performed.

As shown in FIG. 5B, inside the space surrounded by the case 90, the second sealing layer 72 is formed so as not to cover the mounting substrate 30 and the semiconductor element 50. In particular, for example, the filling of a material that forms the second sealing layer 72 is performed so as to cover the control circuit board 60, and the material is thermally cured. Accordingly, the second sealing layer 72 is formed. For example, the second sealing layer 72 is formed from silicone gel. The filling, for example, is performed through at least one of a hole formed in the holder resin layer 80 and a gap between the holder resin layer 80 and the case 90. The forming of the second sealing layer 80 may include forming of the second sealing layer 72 such that the gap 80g is formed between the second sealing layer 72 and the holder resin layer 80.

As shown in FIG. 5C, the first sealing layer 71 is formed so as to cover the mounting substrate 30 and the semiconductor element 50 inside the space surrounded by the case 90. As the material of the first sealing layer 71, for example, silicone oil is used.

In the method for manufacturing a semiconductor device according to the embodiment, the occurrence of a crack in the sealing member and the occurrence of peel-off of the sealing member are suppressed, and therefore, a semiconductor device having high reliability can be manufactured with high efficiency.

In addition, although one semiconductor element 50 is illustrated in the figures referred to in the above-described first to third embodiments, a plurality of the memory devices 50 may be provided in the semiconductor devices according to the embodiments and the method for manufacturing the semiconductor devices.

According to the embodiments, the occurrence of a crack in the sealing member and the occurrence of peel-off of the sealing member are suppressed, and accordingly, a semiconductor device having high reliability and a method for manufacturing the semiconductor device are provided.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

As above, the embodiments of the invention have been described with reference to specific examples. However, the embodiments of the invention are not limited to the specific examples. For example, a specific configuration of each element included in the semiconductor device such as the base board, the holder, the holder terminals, the mounting substrate, the semiconductor element, the control circuit board, the control element, or the case belongs to the scope of the invention, as long as the invention is similarly performed through an appropriate selection of a configuration, which is made by those skilled in the art, from a public domain so as to acquire similar advantages.

Further, any two or more components of the specific examples may be combined within the extent of technical feasibility and are included in the scope of the invention to the extent that the purport of the invention is included.

Other than those, all the semiconductor devices and all the methods of manufacturing thereof that can be implemented through appropriate changes in design, which are made by those skilled in the art, based on the semiconductor devices and the methods of manufacturing thereof described above as the embodiments of the invention belong to the scope of the invention as long as they include the concept of the invention.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device comprising:
a base board;
a mounting substrate provided on the base board;
a semiconductor element provided on the mounting substrate;
a holder provided above the mounting substrate;
a holder terminal held by the holder and electrically connected to the semiconductor element;
a case surrounding the mounting substrate along a side face of the mounting substrate and surrounding the holder along a side face of the holder;
a first sealing layer covering the mounting substrate and the semiconductor element inside a space surrounded by the case; and
a second sealing layer provided on the first sealing layer inside the space surrounded by the case and having a hardness higher than a hardness of the first sealing layer.

2. The device according to claim 1, wherein the first sealing layer and the second sealing layer contain silicone gel.

3. The device according to claim 1, further comprising:
a holder resin layer contacting at least a part of the side face of the case and the holder and a lower face of the holder and having a hardness higher than the hardness of the second sealing layer,
a gap being present between the second sealing layer and the holder resin layer.

4. The device according to claim 3, wherein the holder resin layer contains an epoxy-based resin.

5. The device according to claim 1, further comprising:
a control circuit board provided between the mounting substrate and the holder, including a control element controlling the semiconductor element, and being surrounded by the second sealing layer.

6. The device according to claim 1, wherein penetration of the second sealing layer is lower than penetration of the first sealing layer.

7. The device according to claim 1, wherein penetration of the first sealing layer is 100 or more and 500 or less, and penetration of the second sealing layer is 10 or more and 100 or less.

8. The device according to claim 1, wherein the semiconductor element includes at least one of a power thyristor, a power diode, and a power transistor.

9. The device according to claim 1, wherein the base board includes at least one of a composite material board containing AlSiC and a metal board.

10. The device according to claim 1, wherein the mounting substrate includes a ceramic board.

11. A semiconductor device comprising:
a base board;
a mounting substrate provided on the base board;
a semiconductor element provided on the mounting substrate;
a holder provided above the mounting substrate;
a holder terminal held by the holder and electrically connected to the semiconductor element;
a case surrounding the mounting substrate along a side face of the mounting substrate and surrounding the holder along a side face of the holder;
a first sealing layer covering the mounting substrate and the semiconductor element inside a space surrounded by the case; and
a second sealing layer provided on the first sealing layer inside the space surrounded by the case and being more difficult to be deformed than the first sealing layer.

12. The device according to claim 11, wherein the first sealing layer contains silicone oil.

13. The device according to claim 11, further comprising:
a holder resin layer contacting at least a part of the side face of the case and the holder and a lower face of the holder and having a hardness higher than a hardness of the second sealing layer,
a gap being present between the second sealing layer and the holder resin layer.

14. The device according to claim 13, wherein the holder resin layer contains an epoxy-based resin.

15. The device according to claim 11, further comprising:
a control circuit board provided between the mounting substrate and the holder, including a control element controlling the semiconductor element, and being surrounded by the second sealing layer.

16. The device according to claim 11, wherein penetration of the second sealing layer is lower than penetration of the first sealing layer.

17. The device according to claim 11, wherein the first sealing layer is liquid.

18. The device according to claim 11, wherein the first sealing layer contains silicone oil.

19. A method for manufacturing a semiconductor device including: a base board; a mounting substrate provided on the base board; a semiconductor element provided on the mounting substrate; a holder provided above the mounting substrate; a holder terminal held by the holder and electrically connected to the semiconductor element; a case surrounding the mounting substrate along a side face of the mounting substrate and surrounding the holder along a side face of the holder; and a sealing portion covering the mounting substrate and the semiconductor element inside a space surrounded by the case, the method comprising:
forming a first sealing layer covering the mounting substrate and the semiconductor element inside the space surrounded by the case and forming a part of the sealing portion; and
forming a second sealing layer disposed on the first sealing layer inside the space surrounded by the case, having a hardness higher than a hardness of the first sealing layer, and serving as a part of the sealing portion.

20. The method according to claim 19, wherein penetration of the first sealing layer is 100 or more and 500 or less, and penetration of the second sealing layer is 10 or more and 100 or less.
